(19) United States
(12) Patent Application Publication
(10) Pub. No.: US 2025/0148261 A1
(43) Pub. Date: May 8, 2025

(54) CELL-LEVEL ANALYSIS METHOD OF MEMORY BASED ON GRAPH NEURAL NETWORK AND COMPUTING DEVICE FOR PERFORMING THE SAME

(71) Applicants: RESEARCH COOPERATION FOUNDATION OF YEUNGNAM UNIVERSITY, Gyeongsan-si (KR); POSTECH RESEARCH AND BUSINESS DEVELOPMENT FOUNDATION, Pohang-si (KR)

(72) Inventors: Hyun Chul CHOI, Daegu (KR); Jeong Sik LEE, Uiseong-gun (KR); Rock Hyun BAEK, Pohang-si (KR); Kyeong Rae CHO, Pohang-si (KR)

(73) Assignees: RESEARCH COOPERATION FOUNDATION OF YEUNGNAM UNIVERSITY, Gyeongsan-si (KR); POSTECH RESEARCH AND BUSINESS DEVELOPMENT FOUNDATION, Pohang-si (KR)

(21) Appl. No.: 18/622,741

(22) Filed: Mar. 29, 2024

(30) Foreign Application Priority Data
Nov. 2, 2023 (KR) 10-2023-0149979

(51) Int. Cl. G06N 3/042

(52) U.S. Cl. CPC G06N 3/042

(57) ABSTRACT

Disclosed are a cell-level analysis method of a memory and a computing device for performing the same. The cell-level analysis method of a memory is a cell-level analysis method of a memory that is executed in a computing device including one or more processors and a memory storing one or more programs executed by the one or more processors, the cell-level analysis method including acquiring information on a location of each cell in the memory, generating graph-structured data for a target cell based on the location of each cell in the memory, and training a graph neural network model to predict one or more of an electrical characteristic of the target cell and a program and verify level (PV level) of the target cell by inputting the graph-structured data into the graph neural network model.

### CROSS-REFERENCE TO RELATED APPLICATION(S)

This application claims the benefit under 35 USC § 119(a) of Korean Patent Application No. 10-2023-0149979, filed on Nov. 2, 2023, in the Korean Intellectual Property Office, the entire disclosure of which is incorporated herein by reference for all purposes.

### BACKGROUND

### 1. Field

Embodiments of the present disclosure relate to cell-level analysis technology of a memory.

### 2. Description of Related Art

NAND flash memory is a non-volatile storage medium and is widely used in various fields. In recent years, NAND flash memory has transitioned from a planar (that is, two-dimensional) structure to a three-dimensional structure to achieve higher bit density and lower bit cost. NAND (3D NAND) flash memory with a three-dimensional structure is stacked using more than 128 layers.

Meanwhile, temperature, one of the factors affecting device reliability, has a more complex effect on NAND flash memory with a three-dimensional structure than NAND flash memory with a two-dimensional structure. A cross-temperature effect occurs when the NAND flash memory is read at a temperature different from the temperature used during programming. This may change a threshold voltage Vth of a cell, resulting in a shift in distribution of the threshold voltage Vth as illustrated in FIG. 1. In FIG. 1, a black dotted line represents the distribution of the threshold voltage during programming (25° C.), and blue and red lines represent the distribution of the threshold voltage when the NAND flash memory is read at different temperatures (75° C. and 100° C.).

The shift in the distribution of the threshold voltage Vth varies depending on temperature, and the shifted distribution of the threshold voltage Vth may result in data corruption. The threshold voltage Vth, which changes due to temperature differences between storing data in a cell and reading the data stored in the cell, causes a decrease in stability of the device.

In order to solve the aforementioned problem, studies to model NAND characteristics are underway, but existing studies use data on the block or device level rather than the cell level that makes up the NAND flash memory, so there is a problem in that the reliability and safety of each cell are not analyzed and evaluated.

Examples of the related art include Korean Patent Registration No. 10-2356126 (Jan. 27, 2022).

### SUMMARY

The disclosed embodiments are intended to provide a cell-level analysis method of a memory based on a graph neural network, capable of analyzing memory characteristics at a cell level, and a computing device for performing the same.

In one general aspect, there is provided a cell-level analysis method of a memory that is executed in a computing device including one or more processors and a memory storing one or more programs executed by the one or more processors, the cell-level analysis method including acquiring information on a location of each cell in the memory, generating graph-structured data for a target cell based on the location of each cell in the memory, and training a graph neural network model to predict one or more of an electrical characteristic of the target cell and a program and verify level (PV level) of the target cell by inputting the graph-structured data into the graph neural network model.

In the generating of the graph-structured data, the graph-structured data may be generated by setting the target cell and a cell adjacent to the target cell as nodes in the memory and setting a connection between the target cell and the adjacent cell as an edge.

In the generating of the graph-structured data, the target cell and the adjacent cell may be determined to have a connection relationship of a joint word line when the target cell and the adjacent cell are connected in an XY axis direction based on the target cell and the edge thereof may be expressed as a first type of edge, and the target cell and the adjacent cell may be determined to have a connection relationship of a joint string line when the target cell and the adjacent cell are connected in a Z axis direction based on the target cell and the edge thereof may be expressed as a second type of edge.

The electrical characteristic may be a threshold voltage of the target cell, and in the training, the graph neural network model may have a loss function of Equation below.

$${ℒ}_{{V}_{th}} = {‖ {\overline{V}}_{th , 2} - {V}_{th , 2} ‖}_{2}^{2} \qquad ( Equation )$$

V̅_{th,2}: Threshold voltage predicted by the graph neural network model
V_{th,2}: Threshold voltage as a correct answer

The training may include extracting a node feature from each node of the graph-structured data and extracting an edge feature from each edge, inputting each of the extracted node feature and the edge feature into the graph neural network model, and predicting the electrical characteristic of the target cell in one output channel among a plurality of output channels of the graph neural network model and predicting the PV level of the target cell in remaining output channels among the plurality of output channels.

The electrical characteristic may be a threshold voltage of the target cell, and the cell-level analysis method may further include predicting a PV level minimizing a cross-temperature effect on an erased cell in the memory using the previously trained graph neural network model.

The predicting of the PV level minimizing the cross-temperature effect may include virtually programming any erased cell in the memory into a level of each of a plurality of preset states, generating graph-structured data for a level of each state of the erased cell, and predicting a threshold voltage for the level of each state of the erased cell by inputting the graph-structured data for the level of each state of the erased cell into the trained graph neural network model.

The predicting of the PV level minimizing the cross-temperature effect may further include comparing a difference between the predicted threshold voltage for the level of each state of the erased cell and a preset threshold voltage for the level of the corresponding state and setting a level of a state having the smallest difference to the PV level minimizing the cross-temperature effect.

The electrical characteristic may be a threshold voltage of the target cell, and the cell-level analysis method may further include calculating an influence degree over a cross-temperature effect on each of the target cell and adjacent cells using the previously trained graph neural network model.

The calculating of the influence degree may include selecting a target cell to be analyzed in the memory, generating graph-structured data for the selected target cell, inputting graph-structured data for the target cell into the trained graph neural network model and outputting a predicted threshold voltage for the target cell, calculating a difference between the predicted threshold voltage for the target cell and an initial threshold voltage of the target cell, calculating a gradient of each node of the graph-structured data by back-propagating the calculated difference, and calculating the influence degree over the cross-temperature effect on each of adjacent cells of the target cell through the gradient of each node.

In another general aspect, there is provided a computing device including one or more processors, a memory, and one or more programs, in which the one or more programs are configured to be stored in the memory and executed by the one or more processors, and the one or more programs include instructions for acquiring information on a location of each cell in the memory, instructions for generating graph-structured data for a target cell based on the location of each cell in the memory, and instructions for training a graph neural network model to predict one or more of an electrical characteristic of the target cell and a program and verify level (PV level) of the target cell by inputting the graph-structured data into the graph neural network model.

### BRIEF DESCRIPTION OF THE DRAWINGS

FIG. 1 is a diagram illustrating a cross-temperature effect of NAND flash memory.

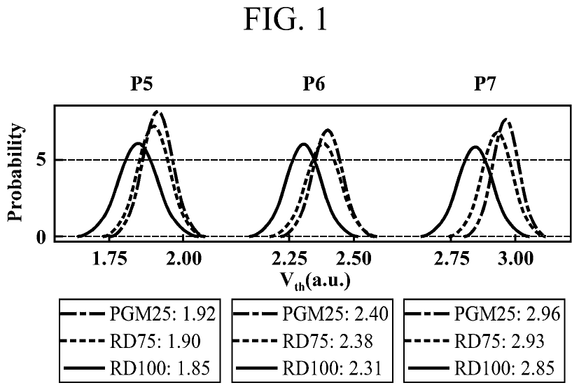

FIG. 2 is a block diagram exemplarily illustrating a computing environment that includes a computing device suitable for use in exemplary embodiments.

FIG. 3 is a flowchart illustrating a cell-level analysis method of 3D NAND flash memory according to one embodiment of the present disclosure.

FIG. 4 is a diagram illustrating coordinates for indicating connection between respective cells of 3D NAND flash memory in one embodiment of the present disclosure.

FIG. 5 is a diagram illustrating a process of generating graph-structured data for a target cell in 3D NAND flash memory in one embodiment of the present disclosure.

FIG. 6 is a diagram illustrating a process of predicting a threshold voltage of a target cell in a graph neural network model using graph-structured data as input in one embodiment of the present disclosure.

FIG. 7 is a diagram illustrating a process of predicting a PV level minimizing a cross-temperature effect on an erased cell in one embodiment of the present disclosure.

FIG. 8 is a diagram schematically illustrating a process of calculating an influence degree affecting the cross-temperature effect in one embodiment of the present disclosure.

### DETAILED DESCRIPTION

Hereinafter, specific embodiments of the present disclosure will be described with reference to the accompanying drawings. The following detailed description is provided to assist in a comprehensive understanding of the methods, devices and/or systems described herein. However, the detailed description is only for illustrative purposes and the present disclosure is not limited thereto.

In describing the embodiments of the present disclosure, when it is determined that detailed descriptions of known technology related to the present disclosure may unnecessarily obscure the gist of the present disclosure, the detailed descriptions thereof will be omitted. The terms used below are defined in consideration of functions in the present disclosure, but may be changed depending on the customary practice, the intention of a user or operator, or the like. Thus, the definitions should be determined based on the overall content of the present specification. The terms used herein are only for describing the embodiments of the present disclosure, and should not be construed as limitative. Unless expressly used otherwise, a singular form includes a plural form. In the present description, the terms “including”, “comprising”, “having”, and the like are used to indicate certain characteristics, numbers, steps, operations, elements, and a portion or combination thereof, but should not be interpreted to preclude one or more other characteristics, numbers, steps, operations, elements, and a portion or combination thereof.

Meanwhile, directional terms such as top, bottom, one side, the other side, and the like, are used in connection with orientations of the disclosed figures. Since components of embodiments of the present disclosure can be positioned in various orientations, the directional terminology is used for purposes of illustration and not limitation.

Further, it will be understood that, although the terms first, second, etc. may be used herein to describe various elements, these elements should not be limited by these terms. These terms may be used to distinguish one element from another element. For example, without departing from the scope of the present disclosure, a first element could be termed a second element, and similarly, a second element could be termed a first element.

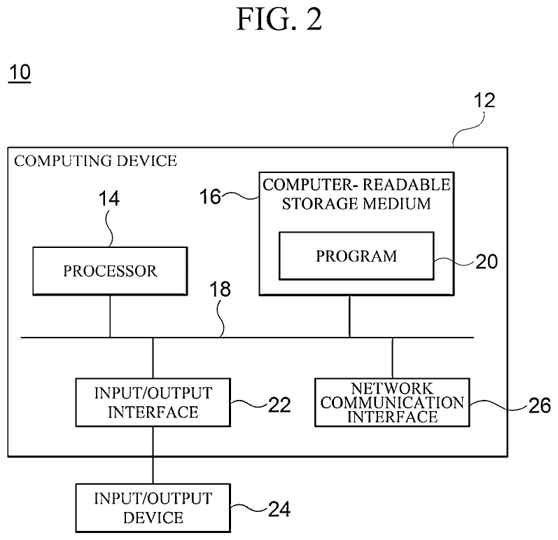

FIG. 2 is a block diagram exemplarily illustrating a computing environment 10 that includes a computing device suitable for use in exemplary embodiments. In the illustrated embodiment, each component may have a different function and capability in addition to those described below, and additional components may be included in addition to those described below.

The illustrated computing environment 10 includes a computing device 12. In one embodiment, the computing device 12 may be a device for cell-level analysis of 3D NAND flash memory. Specifically, the computing device 12 may be a device for modeling interaction of numerous cells existing in the 3D NAND flash memory.

The computing device 12 includes at least one processor 14, a computer-readable storage medium 16, and a communication bus 18. The processor 14 may cause the computing device 12 to operate according to the above-described exemplary embodiments. For example, the processor 14 may execute one or more programs stored in the computer-readable storage medium 16. The one or more programs may include one or more computer-executable instructions, which may be configured to cause, when executed by the processor 14, the computing device 12 to perform operations according to the exemplary embodiments.

The computer-readable storage medium 16 is configured to store computer-executable instructions or program codes, program data, and/or other suitable forms of information. A program 20 stored in the computer-readable storage medium 16 includes a set of instructions executable by the processor 14. In one embodiment, the computer-readable storage medium 16 may be a memory (a volatile memory such as a random access memory, a non-volatile memory, or any suitable combination thereof), one or more magnetic disk storage devices, optical disc storage devices, flash memory devices, other types of storage media that are accessible by the computing device 12 and may store desired information, or any suitable combination thereof.

The communication bus 18 interconnects various other components of the computing device 12, including the processor 14 and the computer-readable storage medium 16.

The computing device 12 may also include one or more input/output interfaces 22 that provide an interface for one or more input/output devices 24, and one or more network communication interfaces 26. The input/output interface 22 and the network communication interface 26 are connected to the communication bus 18. The input/output device 24 may be connected to other components of the computing device 12 via the input/output interface 22. The exemplary input/output device 24 may include a pointing device (a mouse, a trackpad, or the like), a keyboard, a touch input device (a touch pad, a touch screen, or the like), a voice or sound input device, input devices such as various types of sensor devices and/or imaging devices, and/or output devices such as a display device, a printer, an interlocutor, and/or a network card. The exemplary input/output device 24 may be included inside the computing device 12 as one of components constituting the computing device 12, or may be connected to the computing device 12 as a separate device distinct from the computing device 12.

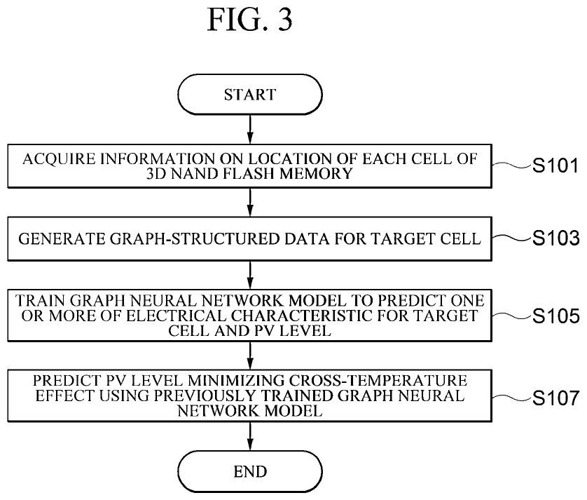

FIG. 3 is a flowchart illustrating a cell-level analysis method of 3D NAND flash memory according to one embodiment of the present disclosure. In the illustrated flowchart, the method is divided into a plurality of steps; however, at least some of the steps may be performed in a different order, performed together in combination with other steps, omitted, performed in subdivided steps, or performed by adding one or more steps not illustrated.

Referring to FIG. 3, the computing device 12 may acquire information on the location of each cell of the 3D NAND flash memory (S101). Here, a cell may refer to a single transistor that constitutes the 3D NAND flash memory. Here, the 3D NAND flash memory is described as an example of a type of memory, but the memory is not limited thereto, and of course, various other types and forms of memory may be applied.

Next, the computing device 12 may generate graph-structured data for a target cell based on the location of each cell of the 3D NAND flash memory (S103).

Here, graph-structured data may be expressed as nodes and edges. The computing device 12 may generate the graph-structured data for the target cell by setting the target cell and a cell adjacent to the target cell as nodes in the 3D NAND flash memory, and setting the connection between the cells as an edge.

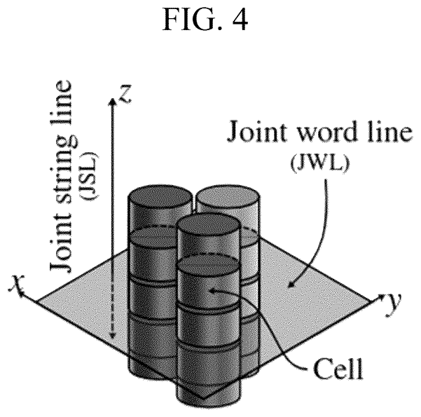

FIG. 4 is a diagram illustrating coordinates for indicating connection between respective cells of 3D NAND flash memory in one embodiment of the present disclosure. Referring to FIG. 4, in the 3D NAND flash memory, cells may be arranged in three axis direction (X-axis, Y-axis, and Z-axis). Here, the connection in the XY axis direction may be defined as a joint word line (JWL), and the connection in the Z axis direction may be defined as a joint string line (JSL).

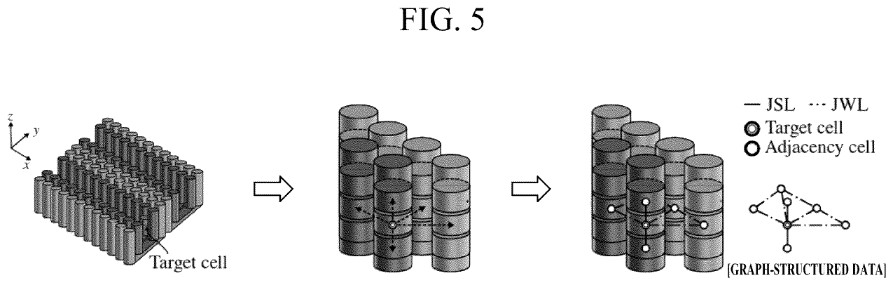

FIG. 5 is a diagram illustrating a process of generating graph-structured data for a target cell in 3D NAND flash memory in one embodiment of the present disclosure. Referring to FIG. 5, the computing device 12 may select a target cell from the 3D NAND flash memory. That is, since the disclosed embodiment is intended to predict cell-level characteristics in the NAND flash memory, one target cell may be selected from the 3D NAND flash memory. The computing device 12 may check a connection relationship with adjacent cells based on the selected target cell.

When an adjacent cell is connected in the XY axis direction based on the target cell, the computing device 12 may determine that the connection relationship is the joint word line (JWL). when an adjacent cell is connected in the Z axis direction based on the target cell, the computing device 12 may determine that the connection relationship is the joint string line (JSL). The computing device 12 may set a target cell and a cell adjacent to the target cell as nodes, and set the connection between the target cell and the adjacent cell as an edge.

In this case, the edge may have two types. When the target cell and an adjacent cell have the connection relationship of the joint word line (JWL), the computing device 12 may express the connection between the target cell and the adjacent cell as a first type of edge (expressed as a one-dash line in FIG. 5). When the target cell and an adjacent cell have the connection relationship of the joint string line (JSL), the computing device 12 may express the connection between the target cell and the adjacent cell as a second type of edge (expressed as a solid line in FIG. 5).

The computing device 12 may store information, such as coordinate values of a corresponding cell (e.g., a column (COL), an input/output (IO), a word line (WL), a string line (STR), or the like), initial temperature (Temp1), target temperature (Temp2), retention time (time taken to change from the initial temperature to the target temperature), initial threshold voltage (Vₜₕ₁), and the like, in each node in the graph-structured data. In addition, the computing device 12 may set a value of the first type of edge to 1 and a value of the second type of edge to 0.

Next, the computing device 12 may train a graph neural network (GNN) model to predict one or more of the electrical characteristic and a PV level (program and verify level) of the target cell by inputting the graph-structured data for the target cell into the graph neural network model (S105).

In one embodiment, the electrical characteristic may be a threshold voltage, but it is not limited thereto, and of course, various other electrical characteristics that may appear in the cell may be included. Hereinafter, a case where the electrical characteristic is the threshold voltage will be described as one example.

Each cell is programmed to have one of levels of a plurality of levels (e.g., E, P1 to P7) according to the distribution of the threshold voltage, where predicting the PV level (program and verify level) of the target cell means predicting which state's level the target cell is programmed into. Here, E may be a level of an erased state (may also be expressed as P0), and P1 to P7 may mean levels of first to seventh states.

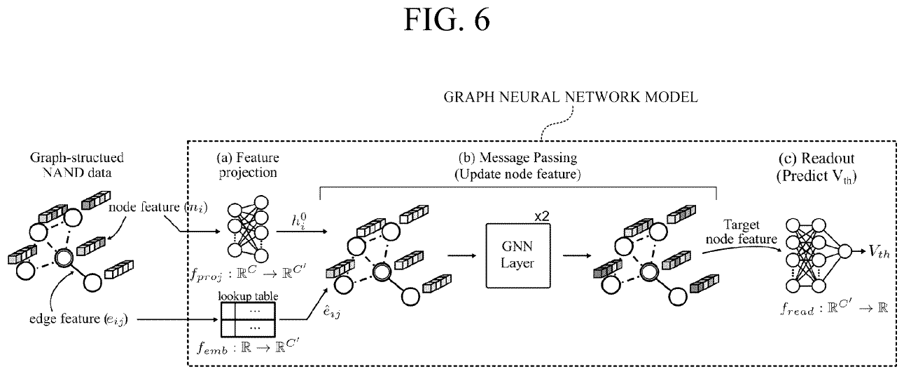

FIG. 6 is a diagram illustrating a process of predicting a threshold voltage Vth of a target cell in a graph neural network model using graph-structured data as input in one embodiment of the present disclosure. Referring to FIG. 6, the computing device 12 may extract a node feature nᵢ from each node and an edge feature eᵢⱼ from each edge in graph-structured data consisting of nodes and edges.

The computing device 12 may input the node feature and the edge feature into the graph neural network model. The graph neural network model may include a plurality of graph neural network layers (GNN Layers). The node feature and the edge feature are input to the plurality of graph neural network layers and are exchanged through the graph neural network layers to update node information. Further, the updated node information may be used to predict the threshold voltage Vth of the corresponding target cell at an output terminal of the graph neural network model.

In this way, the graph neural network model may be trained to predict the threshold voltage Vₜₕ of the corresponding target cell based on the input node feature and edge feature. In this case, the computing device 12 may train the graph neural network model so that a difference between the threshold voltage predicted by the graph neural network model and the threshold voltage as the correct answer value is minimized. In one embodiment, the computing device 12 may train the graph neural network model so that the graph neural network model has a loss function L_{Vth} of Equation 1.

$${ℒ}_{{V}_{th}} = {‖ {\overline{V}}_{th , 2} - {V}_{th , 2} ‖}_{2}^{2} \qquad ( Equation 1 )$$

V̅_{th,2}: Threshold voltage predicted by the graph neural network model
V_{th,2}: Threshold voltage as a correct answer

The graph neural network model may use a previously known model, and since the structure and operation of the graph neural network model are already known technologies, a detailed description thereof will be omitted.

Meanwhile, here, it has been described that the graph neural network model predicts the threshold voltage Vₜₕ of the target cell, but the present disclosure is not limited thereto, and the graph neural network model may be provided to predict the program and verify level (PV level), as well as the threshold voltage Vₜₕ of the target cell, by using the node feature and the edge feature as input.

For example, when the graph neural network model is a multi-task model, the threshold voltage Vₜₕ and PV level of the target cell may be predicted together by using the node feature and the edge feature as input. In this case, the number of the output channels of the graph neural network model may be expanded to nine. One output channel of the graph neural network model may be used to predict the threshold voltage, and the remaining eight output channels may be used to predict the PV level. In addition, since the PV level is matched to the predicted threshold voltage Vₜₕ, when the threshold voltage Vₜₕ is predicted, the corresponding PV level may also be extracted.

Next, the computing device 12 may predict a PV level minimizing a cross-temperature effect on an erased cell (that is, a cell of P0) in the 3D NAND flash memory using the previously trained graph neural network model (S107).

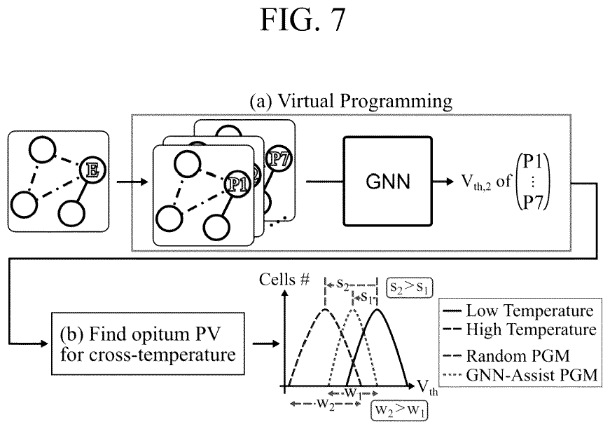

FIG. 7 is a diagram illustrating a process of predicting a PV level minimizing a cross-temperature effect on an erased cell in one embodiment of the present disclosure. Referring to FIG. 7, the computing device 12 may virtually program an erased cell in the 3D NAND flash memory into a level of each of a plurality of preset states (e.g., P1 to P7).

The computing device 12 may generate graph-structured data for the virtually programmed erase cell. The computing device 12 may generate graph-structured data for a level of each state of the erased cell. The computing device 12 may predict a threshold voltage V_{th,2} for the level of each state of the erased cell by inputting the graph-structured data for the level of each state of the erased cell into the previously trained graph neural network model.

The computing device 12 may compare the threshold voltage V_{th,2} predicted for the level of each state of the erase cell and a threshold voltage V_{th,1} preset for the level of the corresponding state and extract a level of a state in which the difference (V_{th,2}−V_{th,1}) is the smallest. The threshold voltage V_{th,1} preset for the level of each state may be randomly selected from a histogram (or average and variance) of the threshold voltage for the level of each state in data of the previously measured cell.

The computing device 12 may be programmed by setting the extracted level of the state to a PV level (level of the state) minimizing the cross-temperature effect in the corresponding erased cell. The computing device 12 may repeat this process for the remaining erased cells in the 3D NAND flash memory. In this case, it can be seen that a shift in distribution of the threshold voltage is reduced from s₂ to s₁, and a width of the distribution of the threshold voltage is reduced from w₂ to w₁.

According to disclosed embodiments, by generating graph-structured data based on locations of cells in a memory and inputting the generated graph-structured data into the graph neural network model to predict an electrical characteristic or PV level, characteristics of the memory may be analyzed at a cell level and thus memory programming may be carried out more precisely and efficiently.

Meanwhile, the computing device 12 may calculate an influence degree affecting the cross-temperature effect of cells of the 3D NAND flash memory using a previously trained graph neural network model. That is, the computing device 12 may calculate the degree to which a cell among cells adjacent to the target cell influences the cross-temperature effect on the target cell.

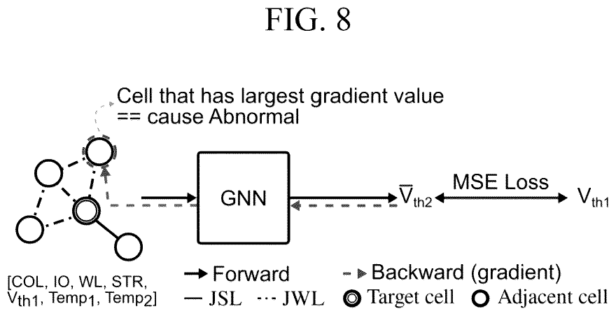

FIG. 8 is a diagram schematically illustrating a process of calculating an influence degree affecting the cross-temperature effect in one embodiment of the present disclosure. Referring to FIG. 8, the computing device 12 may select a target cell that the computing device 12 wishes to analyze in the 3D NAND flash memory. The computing device 12 may generate graph-structured data for the selected target cell. The computing device 12 may input the graph-structured data for the target cell into the previously trained graph neural network model and output a predicted threshold voltage V̅_{th,2} for the target cell.

The computing device 12 may calculate a difference between the predicted threshold voltage for the target cell and an initial threshold voltage Vₜₕ₁ of the target cell. In one embodiment, the computing device 12 may calculate a mean squared error (MSE) between the predicted threshold voltage for the target cell and the initial threshold voltage of the target cell. The computing device 12 may calculate a gradient of each node of the graph-structured data by back-propagating the calculated mean square error (MSE) to the graph-structured data. The computing device 12 may check which cell affects the cross-temperature effect through the calculated gradient of each node (that is, cell).

The computing device may calculate the gradient of each node of the graph-structured data by applying a chain rule to the calculated mean square error (MSE). For example, when an i-th node (i.e., cell) of the graph-structured data is xᵢ, the gradient of the i-th node may be calculated through Equation 2 below.

$$\frac{d}{d {x}_{i}} M S E = \frac{d}{d {x}_{i}} {‖ GNN ( x ) - Y ‖}_{2}^{2} \qquad ( Equation 2 )$$

GNN(x); Threshold voltage predicted by the graph neural network model
Y; Initial threshold voltage of target cell

Here, a gradient value obtained through back-propagation represents the degree to which a difference in threshold voltage occurs due to temperature change. Therefore, it is possible to check the influence degree of the cross-temperature effect on the target cell through the gradient value of each node of the graph-structured data.

According to disclosed embodiments, by generating graph-structured data based on locations of cells in a memory and inputting the generated graph-structured data into the graph neural network model to predict an electrical characteristic or PV level, characteristics of the memory can be analyzed at a cell level and thus memory programming can be carried out more precisely and efficiently.

Although the representative embodiments of the present disclosure have been described in detail as above, those skilled in the art will understand that various modifications may be made thereto without departing from the scope of the present disclosure. Therefore, the scope of rights of the present disclosure should not be limited to the described embodiments, but should be defined not only by the claims set forth below but also by equivalents of the claims.

What is claimed is:

1. A cell-level analysis method of a memory that is executed in a computing device including one or more processors and a memory storing one or more programs executed by the one or more processors, the cell-level analysis method comprising:
acquiring information on a location of each cell in the memory;
generating graph-structured data for a target cell based on the location of each cell in the memory; and
training a graph neural network model to predict one or more of an electrical characteristic of the target cell and a program and verify level (PV level) of the target cell by inputting the graph-structured data into the graph neural network model.

2. The cell-level analysis method of claim 1, wherein in the generating of the graph-structured data, the graph-structured data is generated by setting the target cell and a cell adjacent to the target cell as nodes in the memory and setting a connection between the target cell and the adjacent cell as an edge.

3. The cell-level analysis method of claim 2, wherein in the generating of the graph-structured data, the target cell and the adjacent cell are determined to have a connection relationship of a joint word line when the target cell and the adjacent cell are connected in an XY axis direction based on the target cell, and the edge thereof is expressed as a first type of edge, and
the target cell and the adjacent cell are determined to have a connection relationship of a joint string line when the target cell and the adjacent cell are connected in a Z axis direction based on the target cell and the edge thereof is expressed as a second type of edge.

4. The cell-level analysis method of claim 2, wherein the electrical characteristic is a threshold voltage of the target cell, and
in the training, the graph neural network model has a loss function of Equation below:
(Equation)
$${ℒ}_{{V}_{th}} = {‖ {\overline{V}}_{th , 2} - {V}_{th , 2} ‖}_{2}^{2}$$
V̅_{th,2}: Threshold voltage predicted by the graph neural network model
V_{th,2}: Threshold voltage as a correct answer.

5. The cell-level analysis method of claim 2, wherein the training includes:
extracting a node feature from each node of the graph-structured data and extracting an edge feature from each edge;
inputting each of the extracted node feature and the edge feature into the graph neural network model; and
predicting the electrical characteristic of the target cell in one output channel among a plurality of output channels of the graph neural network model and predicting the PV level of the target cell in remaining output channels among the plurality of output channels.

6. The cell-level analysis method of claim 2, wherein the electrical characteristic is a threshold voltage of the target cell, and
the cell-level analysis method further comprises predicting a PV level minimizing a cross-temperature effect on an erased cell in the memory using the previously trained graph neural network model.

7. The cell-level analysis method of claim 6, wherein the predicting of the PV level minimizing the cross-temperature effect includes:
virtually programming any erased cell in the memory into a level of each of a plurality of preset states;
generating graph-structured data for a level of each state of the erased cell; and
predicting a threshold voltage for the level of each state of the erased cell by inputting the graph-structured data for the level of each state of the erased cell into the trained graph neural network model.

8. The cell-level analysis method of claim 7, wherein the predicting of the PV level minimizing the cross-temperature effect further includes:
comparing a difference between the predicted threshold voltage for the level of each state of the erased cell and a preset threshold voltage for the level of the corresponding state; and
setting a level of a state having the smallest difference to the PV level minimizing the cross-temperature effect.

9. The cell-level analysis method of claim 2, wherein the electrical characteristic is a threshold voltage of the target cell, and
the cell-level analysis method further comprises calculating an influence degree over a cross-temperature effect on each of the target cell and adjacent cells using the previously trained graph neural network model.

10. The cell-level analysis method of claim 9, wherein the calculating of the influence degree includes:
selecting a target cell to be analyzed in the memory;
generating graph-structured data for the selected target cell;
inputting graph-structured data for the target cell into the trained graph neural network model and outputting a predicted threshold voltage for the target cell;
calculating a difference between the predicted threshold voltage for the target cell and an initial threshold voltage of the target cell;
calculating a gradient of each node of the graph-structured data by back-propagating the calculated difference; and
calculating the influence degree over the cross-temperature effect on each of adjacent cells of the target cell through the gradient of each node.

11. A computing device comprising:
one or more processors;
a memory; and
one or more programs,
wherein the one or more programs are configured to be stored in the memory and executed by the one or more processors, and
the one or more programs include:
instructions for acquiring information on a location of each cell in the memory;
instructions for generating graph-structured data for a target cell based on the location of each cell in the memory; and
instructions for training a graph neural network model to predict one or more of an electrical characteristic of the target cell and a program and verify level (PV level) of the target cell by inputting the graph-structured data into the graph neural network model.

12. The computing device of claim 11, wherein in the instructions for generating the graph-structured data, the graph-structured data is generated by setting the target cell and a cell adjacent to the target cell as nodes in the memory and setting a connection between the target cell and the adjacent cell as an edge.

13. The computing device of claim 12, wherein in the instructions for generating the graph-structured data, the target cell and the adjacent cell are determined to have a connection relationship of a joint word line when the target cell and the adjacent cell are connected in an XY axis direction based on the target cell, and the edge thereof is expressed as a first type of edge, and
the target cell and the adjacent cell are determined to have a connection relationship of a joint string line when the target cell and the adjacent cell are connected in a Z axis direction based on the target cell and the edge thereof is expressed as a second type of edge.

14. The computing device of claim 12, wherein the electrical characteristic is a threshold voltage of the target cell, and
the one or more programs further include instructions for predicting a PV level minimizing a cross-temperature effect on an erased cell in the memory using the previously trained graph neural network model.

15. The computing device of claim 14, wherein the instructions for predicting a PV level minimizing a cross-temperature effect include:
instructions for virtually programming any erased cell in the memory into a level of each of a plurality of preset states;
instructions for generating graph-structured data for a level of each state of the erased cell; and
instructions for predicting a threshold voltage for the level of each state of the erased cell by inputting the graph-structured data for the level of each state of the erased cell into the trained graph neural network model.

16. The computing device of claim 15, wherein the instructions for predicting a PV level minimizing a cross-temperature effect further include:
instructions for comparing a difference between the predicted threshold voltage for the level of each state of the erased cell and a preset threshold voltage for the level of the corresponding state; and
instructions for setting a level of a state having the smallest difference to the PV level minimizing the cross-temperature effect.

17. The computing device of claim 12, wherein the electrical characteristic is a threshold voltage of the target cell, and
the one or more programs further include instructions for calculating an influence degree over a cross-temperature effect on each of the target cell and adjacent cells using the previously trained graph neural network model.

18. The computing device of claim 17, wherein the instructions for calculating an influence degree include:
instructions for selecting a target cell to be analyzed in the memory;
instructions for generating graph-structured data for the selected target cell;
instructions for inputting graph-structured data for the target cell into the trained graph neural network model and outputting a predicted threshold voltage for the target cell;
instructions for calculating a difference between the predicted threshold voltage for the target cell and an initial threshold voltage of the target cell;
instructions for calculating a gradient of each node of the graph-structured data by back-propagating the calculated difference; and
instructions for calculating the influence degree over the cross-temperature effect on each of adjacent cells of the target cell through the gradient of each node.

19. A computer program stored in a non-transitory computer readable storage medium, comprising one or more instructions that, when executed by a computing device having one or more processors, cause the computing device to perform operations of:
acquiring information on a location of each cell in the memory;
generating graph-structured data for a target cell based on the location of each cell in the memory; and
training a graph neural network model to predict one or more of an electrical characteristic of the target cell and a program and verify level (PV level) of the target cell by inputting the graph-structured data into the graph neural network model.
